(19) United States
(12) Patent Application Publication
(10) Pub. No.: US 2008/0124901 A1
(43) Pub. Date: May 29, 2008

(54) Method for maintaining semiconductor manufacturing apparatus, semiconductor manufacturing apparatus, and method for manufacturing semiconductor

(75) Inventors: Akira Jyogo, Numazu-shi (JP); Yoshikazu Moriyama, Izu-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: NuFlare Technology, Inc.

(21) Appl. No.: 11/812,745

(22) Filed: Jun. 21, 2007

(30) Foreign Application Priority Data
Jun. 22, 2006 (JP) P2006-172840

(51) Int. Cl. H01L 21/20; C23C 16/56

(52) U.S. Cl. 438/509; 118/725; 257/E21.09

(57) ABSTRACT

A method for maintaining semiconductor manufacturing apparatus, semiconductor manufacturing apparatus, and a method for manufacturing a semiconductor that allow a component to be reused and contamination to a wafer to be suppressed without a need for replacement of the component, are provided. The method for maintaining semiconductor manufacturing apparatus includes, in a reactor in which a component having a base material covered with a first SiC film is installed so as to form a Si epitaxial film on a wafer, forming a second SiC film on a surface of the component with at least part of the first SiC film sublimated while repeating a process.

### CROSS-REFERENCE TO RELATED APPLICATIONS

This application is based upon and claims the benefit of priority from the prior Japanese Patent Application No. 2006-172840 filed on Jun. 22, 2006, the entire contents of which are incorporated herein by reference.

### BACKGROUND OF THE INVENTION

1. Field of the Invention

The present invention relates to a method for maintaining semiconductor manufacturing apparatus, semiconductor manufacturing apparatus, and a method for manufacturing a semiconductor that use a component, such as a heater or a wafer holder, having a base material covered with a SiC film.

2. Description of the Related Art

Generally in an epitaxial growth system, a wafer is placed in a reactor and a process gas is supplied onto the wafer under predetermined conditions. The wafer is heated while being rotated, so that an epitaxial film is formed.

At this time, a holder for mounting a wafer, a heater for heating a wafer, and the like are installed in the reactor. Components each having a base material made of carbon, SiC, or the like, which is highly stable against high temperature, covered with a high-purity SiC film are used for the holder and heater. The base material is usually formed by powder sintering, and therefore contains impurities such as Fe, Ni, Cr, and Zn. Contamination to the wafer and inside of the reactor caused by the impurities can be suppressed by the high-purity SiC film, which is usually formed by a chemical vapor deposition (CVD) method.

However, there is a problem in that the SiC film is sublimated while a high temperature process is repeated, and thus part of the base material is exposed. For example, sublimation of the SiC film proceeds in a portion that reaches a temperature higher than other portions of the high-temperature heater, and thus part of the base material corresponding to the portion is exposed. If the part of the base material is exposed, the component needs to be replaced independently of deterioration of the base material itself.

In recent years, when an epitaxial film is formed, SiHCl₃ has tended to be used, instead of conventionally used SiH₄, as a source gas to meet the demands for improvement in productivity and improvement in film quality. With the change of the source gas, the film formation temperature has increased from 1000° C. to 1120° C. This increase in film formation temperature accelerates deterioration of a SiC film due to its sublimation. Therefore, the frequency, component cost, and time required for replacing a component have also increased.

Regarding reduction of the component cost, a technique of removing a SiC film from a component and covering the component with a SiC film is proposed in, for example, claim 1 of Japanese Patent Application Laid-Open No. 2002-37684. Such a technique, however, requires replacement of a component. Thus, there is a shortcoming in that reduction of non-operating time associated with replacement is difficult.

### SUMMARY OF THE INVENTION

An object of the present invention is to provide a method for maintaining semiconductor manufacturing apparatus, semiconductor manufacturing apparatus, and a method for manufacturing a semiconductor that allow a component to be reused and contamination to a wafer to be suppressed without a need for replacement of the component.

A method for maintaining semiconductor manufacturing apparatus for forming a Si epitaxial film on a wafer according to one aspect of the invention includes, installing a component having a base material covered with a first SiC film in a reactor configured to form a Si epitaxial film on the wafer therein, and forming a second SiC film on a surface of the component with at least part of the first SiC film sublimated while repeating a high temperature process.

Also, semiconductor manufacturing apparatus according to another aspect of the invention includes a reactor for forming a Si epitaxial film on the wafer, a supply port for supplying at least a Si source gas and a SiC source gas to the reactor, a support unit for holding the wafer, a heating mechanism for heating the wafer, and a component having at least part of a base material covered with a SiC film and the component installed in the reactor.

Further, a method for manufacturing a semiconductor according to another aspect of the invention includes, first, covering a surface of a component with a second SiC film, the component installed in a reactor and the component having a base material covered with a first SiC film, mounting a wafer on a support unit installed in the reactor, supplying a process gas into the reactor for forming a Si epitaxial film on the wafer, and heating the wafer to form the Si epitaxial film on the wafer.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the forgoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate an embodiment of the invention and together with the description, serve to explain the principles of the invention.

FIG. 1 is a cross-sectional view of semiconductor manufacturing apparatus according to an aspect of the invention;

FIG. 2 is a partial cross-sectional view of a heater having a base material covered with a SiC film in its initial state in an aspect of the invention;

FIG. 3 is a partial cross-sectional view of the heater having the base material covered with the SiC film after one month has passed in an aspect of the invention;

FIG. 4 is a partial cross-sectional view of the heater having the base material covered again with a SiC film in an aspect of the invention;

FIG. 5 is a partial cross-sectional view of a heater having a base material covered with a SiC film in its initial state in an aspect of the invention; and

FIG. 6 is a partial cross-sectional view of a heater having the base material covered again with a SiC film in an embodiment of the invention.

### DETAILED DESCRIPTION OF THE EMBODIMENT

Reference will now be made in detail to the present embodiment of the invention, an example of which is illustrated in the accompanying drawings. Wherever possible, the same reference numbers will be used throughout the drawings to refer to the same or like parts.

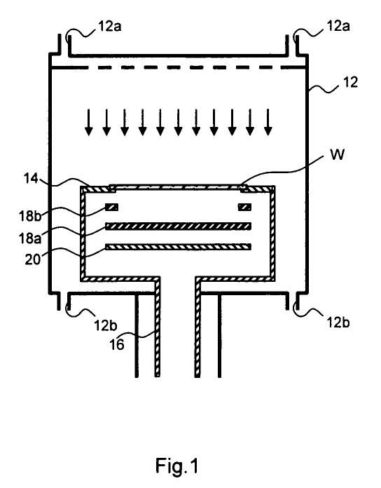

FIG. 1 shows a cross-sectional view of semiconductor manufacturing apparatus according to the present embodiment. As shown in the figure, a reactor 12 for forming a film on a wafer w is provided. A holder 14 for holding the wafer w is placed in the reactor 12; a rotating mechanism 16 is connected to the wafer w for rotating the wafer. Heaters 18a and 18b for heating the wafer w and a reflector 20 for effectively heating the wafer w are also installed in the reactor 12. The reactor 12 is also provided with supply ports 12a for supplying a process gas including a Si source gas, a dopant gas, and a carrier gas and a SiC source gas, and exhaust ports 12b for exhausting the gases. The holder 14 and the heaters 18a and 18b are constituted of components each having a base material covered with a SiC film. The base material is made of carbon or sintered SiC.

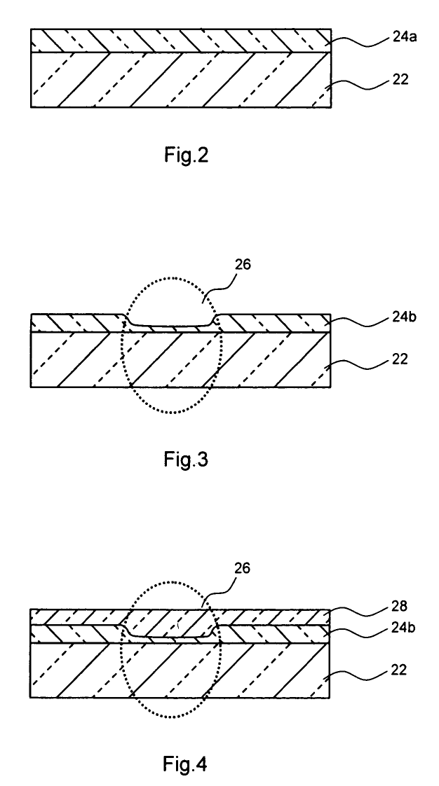

FIG. 2 shows a partial cross-sectional view of a heater having a base material covered with a SiC film in its initial state. As shown in the figure, a SiC initial film 24a is formed uniformly on a base material 22.

A Si film is formed on the wafer w using such. semiconductor manufacturing apparatus. At this point, process conditions are set, for example, as follows:

process temperature: 1100 to 1150° C.

reactor internal pressure: 80 to 101.3 KPa (600 to 760 torr)

source gas, flow rate: SiHCl₃, 20 to 35 slm

dopant gas, flow rate: PH₃, 200 to 250 slm→40 to 60 slm

carrier gas, flow rate: H₂, 100 to 120 slm

wafer rotational speed: 800 to 1000 rpm

Note that the heater temperature needs to be about 1500° C. in order for the wafer temperature to be set to the preset temperature. Under these conditions, semiconductor manufacturing apparatus is operated, thereby forming Si films on a plurality of wafers w.

SiC initial films, which are formed on surfaces of components such as the holder 14 and the heaters 18a and 18b installed in the reactor by operating semiconductor manufacturing apparatus under the above-described conditions, are gradually sublimated. FIG. 3 shows a partial cross-sectional view of a heater having a base material covered with the SiC initial film after one month (as an example) has passed. As shown in the figure, sublimation is caused in the surface of a SiC initial film 24b formed on a surface of the base material 22. Although the entire surface of the base material of the component is covered with the SiC initial film, sublimation partially proceeds in a region 26 where temperature becomes particularly high. The SiC initial film is thinned in the region. The thickness distribution of the SiC initial film at this point is wide as compared to that of ±0.8% in the initial state of the film, and exhibits a wide variation from ±1.5% to ±2%.

In such a state that part of the SiC initial film is thinned, a source gas for forming a SiC film is introduced into the semiconductor manufacturing apparatus. At this point, process conditions are set, for example, as follows:

preset temperature: 1000 to 1500° C.

reactor internal pressure: near-normal pressure

source gas, flow rate: CH₃SiH₃, 10 sccm

carrier gas, flow rate: H₂, 50 slm

Under such conditions, a new SiC film of about 20 to 100 μm is formed, and the base material is covered again with this new SiC film. As shown in FIG. 4, a SiC re-covering film 28 is newly formed on the thinned SiC initial film 24b.

In this way, a SiC re-covering film is repeatedly formed with the component remaining in the reactor before exposure of the base material. The component, which has conventionally required replacement, can thus be repeatedly reused. In the embodiment, the component only needs to be replaced by deterioration of a base material and other connection portions, which have longer life than a SiC film. Therefore, replacement interval can be extended from one month to six months, for example. As a result, the component cost can be reduced to one sixth.

In replacement of the component, the temperature of semiconductor manufacturing apparatus is decreased to the normal temperature, and the semiconductor manufacturing apparatus is restarted after replacement. The replacement usually requires about 48 hours. In the embodiment, the temperature of the semiconductor manufacturing apparatus needs not to be decreased, and a time period for controlling a SiC film formation conditions and forming the SiC film is about 8 hours or less. As a result, the maintenance cost can be reduced to one thirty-sixth or less.

Since the speed of forming a SiC film becomes higher selectively in a high temperature region where a SiC film is thinned, the thickness of the SiC film tends to be uniform. As a result, a variation in heat distribution due to a variation in thickness of the SiC film of a heater can be suppressed. Further, a Si epitaxial film formed on a wafer w can be made uniform.

In the embodiment, CH₃SiH₃ has been mentioned as a source gas for forming a SiC film. The source gas is not limited to the above gas. Another source gas with which a good SiC film is formed can be accepted. Process conditions may be set, for example, as follows:

preset temperature: 1000 to 1500° C.

reactor internal pressure: near-normal pressure

source gas, flow rate: C₂H₂, 50 to 100 sccm SiH₄, 5 sccm

carrier gas, flow rate: H₂, 50 slm

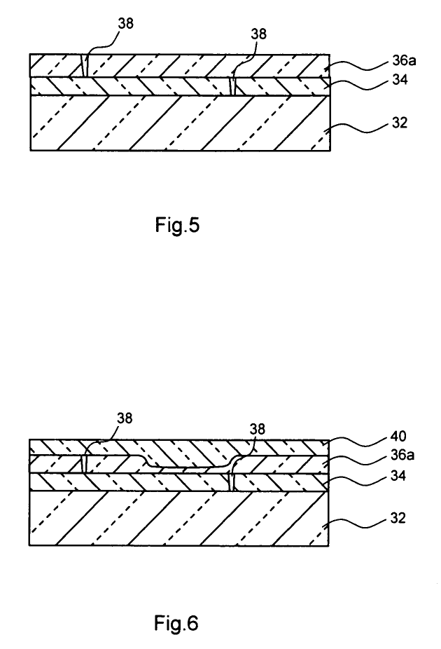

In the embodiment, a SiC initial film of one layer has been mentioned. Forming SiC initial films 34 and 36a composed of two layers in their initial state, as shown in FIG. 5, can suppress effects of pin holes 38 and cracks to a base material 32. In such a case, it is preferable that a SiC re-covering film 40 be formed on a SiC initial film 36b with the sublimated part, which is the upper layer, before exposure of the SiC initial film 34, which is the lower layer.

Further, a SiC re-covering film having weak adhesion (different atomic ratios) may be removed by carrying out cleaning if necessary after formation of the SiC film. Cleaning conditions may be set, for example, as follows:

heater temperature: 1000 to 1200° C.

reactor internal pressure: 93.3 KPa (700 torr)

cleaning gas, flow rate: H₂: HCl=10 slm: 10 slm

After a component in a reactor of semiconductor manufacturing apparatus has been covered again with a SiC film as described above, an epitaxial film is formed on a semiconductor wafer, and a semiconductor device is formed through an element formation process. By the technique of the embodiment, uniform epitaxial films can be formed with high productivity and metal contamination can be stably suppressed. Therefore, the technique is particularly effective for formation of a semiconductor device that requires formation of a thick film. For example, the technique is preferable for formation of high withstand voltage semiconductor devices such as Power MOSFETs and insulated gate bipolar transistors (IGBT), which require epitaxial growth of a thick film of about several tens of micrometers.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method for maintaining semiconductor manufacturing apparatus for forming a Si epitaxial film on a wafer,
the method comprising:
installing a component having a base material covered with a first SiC film in a reactor configured to form a Si epitaxial film on the wafer therein, and
forming a second SiC film on a surface of the component with at least part of the first SiC film sublimated while repeating a process.

2. The method according to claim 1, wherein the second SiC film is formed by supplying a SiC source gas into the reactor.

3. The method according to claim 1, wherein the second SiC film is formed with the base material being unexposed.

4. The method according to claim 3, wherein the first SiC film comprises at least two layers of SiC film, and the second SiC film is formed with at least the first SiC film of a bottom layer being unexposed.

5. The method according to claim 1, further comprising removing part of the second SiC film by using a cleaning gas after formation of the second SiC film.

6. The method according to claim 1, wherein the component is one of a holder for mounting the wafer and a heater for heating the wafer.

7. The method according to claim 1, wherein the base material of the component is carbon or SiC.

8. A semiconductor manufacturing apparatus for forming a Si epitaxial film on a wafer, the apparatus comprising:
a reactor for forming a Si epitaxial film on the wafer,;
a supply port for supplying at least a Si source gas and a SiC source gas to the reactor;
a support unit for holding the wafer;
a heating mechanism for heating the wafer; and
a component having at least part of a base material covered with a SiC film and the component installed in the reactor.

9. The apparatus according to claim 8, wherein the SiC film is composed of at least two layers.

10. The apparatus according to claim 8, wherein the component is a holder for mounting the wafer and/or a heater for heating the wafer.

11. The apparatus according to claim 8, wherein the base material of the component is carbon or SiC.

12. The apparatus according to claim 8, wherein the SiC source gas includes CH₃SiH₃ and/or C₂H₂+SiH₄.

13. The apparatus according to claim 8, wherein the supply port supplies a cleaning gas to the reactor additionally.

14. A method for manufacturing a semiconductor, comprising:
covering a surface of a component with a second SiC film, the component installed in a reactor and the component having a base material covered with a first SiC film;
mounting a wafer on a support unit installed in the reactor;
supplying a process gas into the reactor for forming a Si epitaxial film on the wafer; and
heating the wafer to form the Si epitaxial film on the wafer.

15. The method for manufacturing a semiconductor according to claim 14, wherein the second SiC film is formed by supplying a SiC source gas into the reactor.

16. The method for manufacturing a semiconductor according to claim 14, further comprising covering the surface of the component with a third SiC film after forming the Si epitaxial film on the wafer and taking the wafer out of the reactor.

17. The method for manufacturing a semiconductor according to claim 14, wherein the wafer is heated at temperatures from 1100 to 1500° C.

18. The method for manufacturing a semiconductor according to claim 14, wherein part of the second SiC film is removed by cleaning after the surface of the component is covered with the second SiC film.

19. The method for manufacturing a semiconductor according to claim 14, wherein the component is a holder for mounting the wafer and/or a heater for heating the wafer.

20. The method for manufacturing a semiconductor according to claim 14, wherein the base material of the component is carbon or SiC.
